(19) United States
(12) Patent Application Publication
(10) Pub. No.: US 2025/0311202 A1
(43) Pub. Date: Oct. 2, 2025

(54) MEMORY DEVICE AND MANUFACTURING METHOD THEREOF

(71) Applicant: Winbond Electronics Corp., Taichung City (TW)

(72) Inventor: Hsueh-Cheng Liao, Yunlin (TW)

(73) Assignee: Winbond Electronics Corp., Taichung City (TW)

(21) Appl. No.: 19/071,755

(22) Filed: Mar. 6, 2025

(30) Foreign Application Priority Data
Mar. 26, 2024 (TW) 113111259

(51) Int. Cl. H10B 12/00

(52) U.S. Cl. CPC H10B 12/485; H10B 12/0335

(57) ABSTRACT

A memory device, including: first and second active regions, formed in a substrate; first and second word lines, penetrating through the first and second active regions along a first direction; a bit line stack structure, including a bit line, extending along a second direction and intersecting the first active region, and a bit line contact structure, connecting the bit line to the first active region; a capacitor contact structure, connecting the second active region to a storage capacitor above and located between the first and second word lines; and a spacer, laterally covering the capacitor contact structure and having a portion extending between the bit line stack structure and the capacitor contact structure. The bit line contact structure extends into the first active region in a manner that a bottom end thereof and the portion of the spacer being lower than a topmost surface of the substrate.

### CROSS-REFERENCE TO RELATED APPLICATION

This application claims the priority benefit of Taiwan application serial no. 113111259, filed on Mar. 26, 2024. The entirety of the above-mentioned patent application is hereby incorporated by reference herein and made a part of this specification.

### BACKGROUND

### Technical Field

The disclosure relates to a semiconductor device and a manufacturing method thereof, and in particular to a memory device and a manufacturing method thereof.

### Description of Related Art

With the development of dynamic random access memory (DRAM) processes, the integration density of DRAM has been increasing. The increase in integration density includes reduction of widths and pitches of active regions of access transistors. By disposing DRAM cells more densely, more DRAM cells can be disposed in a given area, thereby increasing the storage density of DRAM. However, this miniaturization may lead to leakage paths between adjacent DRAM cells resulting from inevitable overlay errors.

### SUMMARY

The disclosure provides a memory device and a manufacturing method thereof, which effectively block a leakage path between a capacitor contact structure and an adjacent bit line contact structure, further improving the crosstalk issue between memory cells.

A memory device according to some embodiments of the disclosure includes: a first active region and a second active region located separately in a substrate; a first word line and a second word line extending along a first direction, and penetrating the first active region and the second active region respectively; a bit line stack structure that includes a bit line, extending along a second direction and intersecting the first active region from above the substrate, and a bit line contact structure located between the first word line and the second word line and connecting the bit line to the first active region; a capacitor contact structure connecting the second active region to a storage capacitor above and located between the first word line and the second word line; and a spacer covering a side wall of the capacitor contact structure and having a first portion extending between the bit line stack structure and the capacitor contact structure. The bit line contact structure extends into the first active region in a manner that a bottom end of the bit line contact structure is lower than a topmost surface of the substrate. A bottom end of the first portion of the spacer is also lower than the topmost surface of the substrate.

A manufacturing method of a memory device according to some embodiments of the disclosure includes the following steps. A first active region and a second active region separated from each other are defined in a substrate. A first word line and a second word line, extending along a first direction and penetrating the first active region and the second active region respectively, are formed in the substrate. A bit line stack structure is formed on the substrate. The bit line stack structure includes a bit line, extending along a second direction and intersecting the first active region from above the substrate, and a bit line contact structure located between the first word line and the second word line and connecting the bit line to the first active region. A capacitor contact structure is formed on the substrate, connecting the second active region to a storage capacitor above and located between the first word line and the second word line. A spacer extending between the bit line stack structure and the capacitor contact structure is formed. The bit line contact structure extends into the first active region in a manner that a bottom end of the bit line contact structure is lower than a topmost surface of the substrate. A bottom end of the spacer is also lower than the topmost surface of the substrate.

### BRIEF DESCRIPTION OF THE DRAWINGS

FIG. 1A is a schematic plan view of a memory device according to some embodiments of the disclosure.

FIG. 1B is a schematic cross-sectional view taken along Line X-X′ in FIG. 1A.

FIG. 1C is a schematic cross-sectional view along Line X-X′ in FIG. 1A under a condition where an alignment error exists.

FIGS. 2A to 2J are schematic cross-sectional views along Line X-X′ of an intermediate structure at each stage of a manufacturing process of a semiconductor device.

### DESCRIPTION OF THE EMBODIMENTS

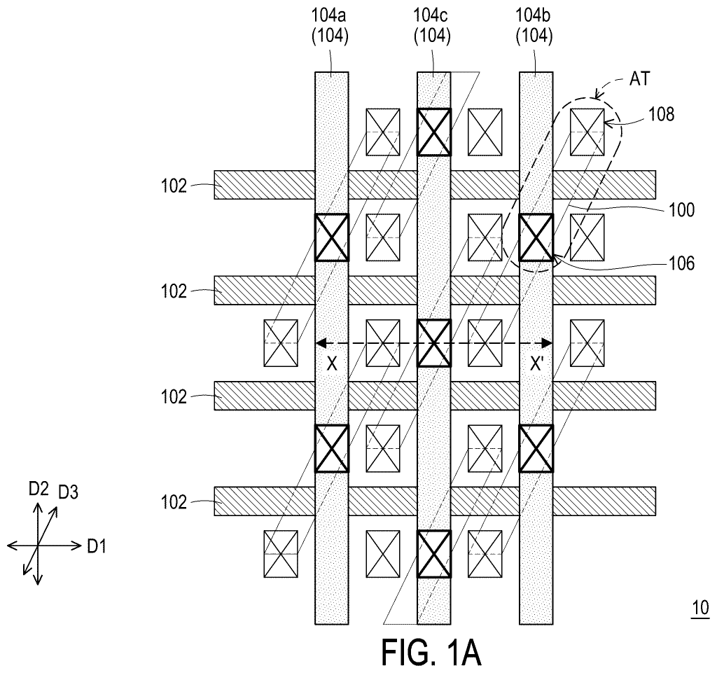

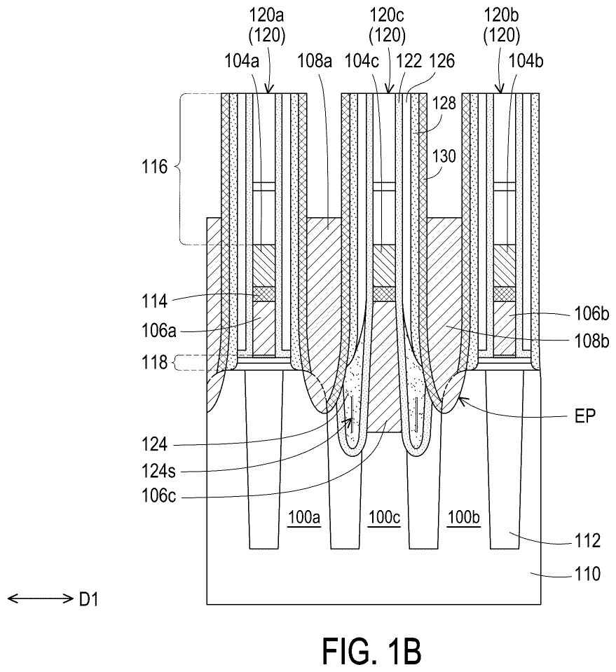

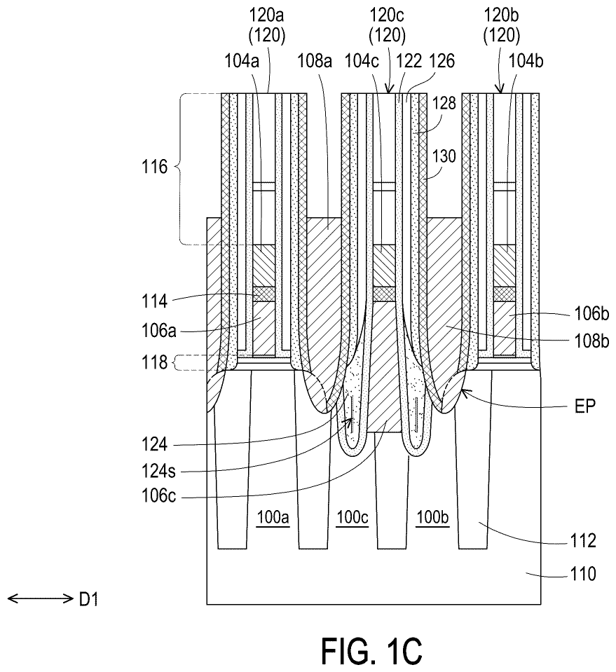

FIG. 1A is a schematic plan view of a memory device 10 according to some embodiments of the disclosure. Referring to FIG. 1A, the memory device 10, as a dynamic random access memory (DRAM), includes multiple active regions 100 arranged along a row direction D1 and a column direction D2. As will be described with reference to FIG. 1B, the active regions 100 are multiple portions of a substrate, separated by isolation structures. In some embodiments, the active regions 100 extends in a direction D3 that intersects the column direction D1 and the row direction D2. Furthermore, in some embodiments, the active regions 100 in each row are offset relative to the active regions 100 in two adjacent rows, and the active regions 100 in each column are offset relative to the active regions 100 in an adjacent column.

Multiple word lines 102 extend along the row direction D1 and pass through the active regions 100. Access transistors AT of memory cells are respectively defined in a region where a word line 102 intersects an active region 100. For each access transistor AT, the penetrating word line 102 serves as a gate, and the portions of the active region 100 on either side of the penetrating word line 102 serve as a drain and a source. In some embodiments, an active region 100 is penetrated by two word lines 102 and shared by two access transistors AT. In the embodiments, the portion of each active region 100 between the two penetrating word lines 102 may serve as a common source/drain for the two access transistors AT sharing the active region 100.

Multiple bit lines 104 extend along the column direction D2 across the active regions 100. One of the sources/drains of the access transistors AT is connected to a bit line 104 intersecting other bit lines 104 through a bit line contact structure 106. In an embodiment where each active region 100 is shared by two access transistors AT, the bit line 104 connects to the portion of each active region 100 serving as a common source/drain through the bit line contact structure 106.

Another source/drain of the access transistor AT is connected to a storage capacitor above (not shown) through a capacitor contact structure 108. This way, one of the sources/drains of each access transistor AT is connected to a bit line 104 while another source/drain is connected to the storage capacitor. In an embodiment where each active region 100 is shared by two access transistors AT, the portions of the active region 100 on opposite sides of two penetrating word lines 102 and serving as uncommon sources/drains are connected to corresponding storage capacitors through two capacitor contact structures 108.

FIG. 1B is a schematic cross-sectional view taken along Line X-X′ in FIG. 1A, showing three bit lines 104a, 104b, and 104c, bit line contact structures 106a, 106b and 106c below the bit lines 104a to 104c, and capacitor contact structures 108a and 108b between each pair of the bit line and the bit line contact structure.

Referring to FIG. 1B, the bit line 104, the bit line contact structure 106, and the capacitor contact structure 108 are formed on a substrate 110 formed with semiconductor materials. The active regions 100 are portions of the substrate 110 and are separated from each other laterally by an isolation structure 112. Active regions 100a and 100b are connected to the capacitor contact structures 108a and 108b respectively, and an active region 100c is connected to the bit line 104c through the bit line contact structure 106c.

The bit line contact structure 106c establishes an electrical connection with the active region 100c by extending downward into the active region 100c. This way, a bottom end of the bit line contact structure 106c is lower than a topmost surface of the substrate 110. In some embodiments, the bit line 104c is connected to the bit line contact structure 106c through an adhesive layer 114. Additionally, several insulation layers 116 may be stacked above the bit line 104c. Similarly, other bit lines (e.g., the bit lines 104a and 104b) are also connected to the bit line contact structure 106 below (e.g., the bit line contact structure 106a below the bit line 104a or the bit line contact structure 106b below the bit line 104b) through the adhesive layer 114 respectively, and are covered by the insulation layers 116. In an embodiment where the bit line 104 is composed of tungsten and the bit line contact structure 106 is composed of polysilicon, the adhesive layer 114 may be composed of, e.g., titanium nitride. Additionally, in some embodiments, the stacking of the insulation layers 116 may include a combination of silicon oxide layers and silicon nitride layers.

Compared to the bit line contact structure 106c that extends into the active region 100c, the bit line contact structures 106a and 106b do not extend into or connect to the active regions 100a and 100b. The bit line contact structures 106a and 106b are located on the isolation structure 112, and the bottom surfaces of the bit line contact structures 106a and 106b are higher than the top surfaces of the isolation structure 112 and the active regions 100a and 100b. In some embodiments, the bit line contact structures 106a and 106b are separated from the isolation structure 112 by one or more insulation layers 118, and the insulation layers 118 may further extend over adjacent active regions 100 (including the active regions 100a and 100b).

Each bit line 104, together with the bit line contact structure 106 and the insulation layer 116 extending in the same direction (i.e., the column direction D2) on both sides above and below, forms a bit line stack structure 120. The bit line stack structure 120 including the bit line 104a and the bit line contact structure 106a is referred to as a bit line stack structure 120a. The bit line stack structure 120 including the bit line 104b and the bit line contact structure 106b is referred to as a bit line stack structure 120b. The bit line stack structure 120 including the bit line 104c and the bit line contact structure 106c is referred to as a bit line stack structure 120c.

Each bit line stack structure 120 is separated from an adjacent capacitor contact structure 108 laterally by multiple layers of spacers. As the innermost spacer, a spacer 122 extends along a side wall of each bit line stack structure 120 and may further extend outwardly at the bottom end. The spacer 122 covering the bit line stack structure 120c further extends outward into the surrounding isolation structure 112 and may extend downward to a position lower than the bottom end of the bit line contact structure 106c of the bit line stack structure 120c. In addition, the spacer 122 covering the bit line stack structure 120c extends at the bottom end and conformally along the surfaces of the recesses on two opposite sides of the bit line stack structure 120c, creating a U-shaped structure from a cross-sectional view. Furthermore, an insulating material 124 may be filled in the recess. In some embodiments, an air gap 124s may be formed within the insulating material 124.

On the other hand, the innermost spacer 122 covering the bit line stack structures 120a and 120b has an extended portion that extends laterally over the isolation structure 112 at the bottom end. In an embodiment where the bit line stack structures 120a and 120b are separated from the isolation structure 112 and the active region 100 (including the active region 100a/100b) below by one or more insulation layers 118, the innermost spacer 122 covering the bit line stack structures 120a and 120b extends laterally over the insulation layers 118 through the extended portion at the bottom.

Each bit line stack structure 120 may also be covered by spacers 126 and 128. The spacer 126 extends downward from a top end of each bit line stack structure 120 along a longitudinal surface of the innermost spacer 122 while the spacer 128 covers an outer surface of the spacer 126. The spacers 126 and 128 covering the bit line stack structure 120c at least partially cover the insulating material 124. On the other hand, a bottom end of the spacer 126 covering the bit line stack structures 120a and 120b may contact the extended portion of the covered innermost spacer 122 at the bottom end. A bottom end of the spacer 128 covering the bit line stack structures 120a and 120b may laterally contact the extended portion of the covered spacer 122 at the bottom end and the insulation layer 118.

In addition, each bit line stack structure 120 further has an outermost spacer 130 on the side wall. The spacer 130 covers other spacers (e.g., the spacers 122, 126, and 128) and laterally surrounds the capacitor contact structure 108 (including the capacitor contact structures 108a and 108b) located between adjacent bit line stack structures 120. The spacer 130 surrounding the capacitor contact structures 108a and 108b may extend downward along the side walls of the capacitor contact structures 108a and 108b facing the bit line stack structure 120c to a position lower than the topmost surface of the substrate 110. More specifically, the spacer 130 surrounding the capacitor contact structures 108a and 108b not only laterally covers the spacer 128 covering bit line stack structure 120c but also extends downward to cover the insulating materials 124 on both sides of the bit line stack structure 120c, an outer edge at the bottom of the U-shaped innermost spacer 122, and the isolation structure 112.

On the other hand, the spacer 130 surrounding the capacitor contact structures 108a and 108b extends downward along a surface of the spacer 128 covering the bit line stack structures 120a and 120b. However, in the cross-sectional view shown in FIG. 1B, the extension generally stops at the topmost surface of the substrate 110. The portion of the spacer 130 covering the bit line stack structures 120a and 120b does not extend to the bottommost portions of the capacitor contact structures 108a and 108b, enabling the active regions 100a and 100b below to remain physically and electrically connected to the capacitor contact structures 108a and 108b through portions that are not covered by the spacer 130.

More specifically, the capacitor contact structure 108 includes an epitaxial portion EP that grows upward along a surface of the recess in the active region 100. The epitaxial portion EP penetrates the spacer 130, thereby connecting the active region 100 to the remaining portion of the capacitor contact structure 108. It is evident that the spacer 130 is discontinuous at a position where the epitaxial portion EP of the capacitor contact structure 108 is located. For example, the spacer 130 surrounding the capacitor contact structure 108a may contact the bottom and top ends of the epitaxial portion EP of the capacitor contact structure 108a without completely covering the epitaxial portion EP. Similarly, the spacer 130 surrounding the capacitor contact structure 108b may contact the bottom and top ends of the epitaxial portion EP of the capacitor contact structure 108b without completely covering the epitaxial portion EP.

As mentioned, the spacer 130 is discontinuous at the position where the epitaxial portion EP of the capacitor contact structure 108 is located, which enables the remaining portion of the capacitor contact structure 108 to physically contact the epitaxial portion EP and be connected to the active region 100 through the epitaxial portion EP. Specifically, the remaining portion of the capacitor contact structure 108 may be deposited on the epitaxial portion EP, thereby filling an opening between the bit line stack structures 120. In some embodiments, after the deposition, a height of a top surface of the capacitor contact structure 108 may be adjusted so that the adjusted top surface of the capacitor contact structure 108 is lower than a top surface of the bit line stack structure 120. Additionally, in some embodiments, the capacitor contact structure 108 (including the epitaxial portion EP) is composed of polysilicon.

Through the disposition of the spacer 130, even in the presence of alignment errors, an unintended electrical connection between the capacitor contact structure 108 and the adjacent bit line contact structure 106 as well as the adjacent bit line 104 through the active region 100 may be avoided.

FIG. 1C is a schematic cross-sectional view along Line X-X′ in FIG. 1A under a condition where an alignment error exists. The alignment error refers to an alignment error generated with the bit line stack structure 120 being relative to the active region 100. Originally, the bit line stack structure 120c should align with the active region 100c (as shown in FIG. 1B).

However, under the condition where an alignment error exists, the bit line stack structure 120c may be displaced relative to the active region 100c and, for example, be positioned on the isolation structure 112 between the active regions 100b and 100c (as shown in FIG. 1C). The alignment error might cause the capacitor contact structure 108a to overlap the active region 100c. If without the spacer 130, a leakage path reaching the bit line contact structure 106c from the capacitor contact structure 108a through the active region 100c might be formed. In other words, through the disposition of the spacer 130, the spacer 130 may extend between the capacitor contact structure 108a and the active region 100c, effectively blocking the leakage path so as to prevent interference between adjacent memory cells.

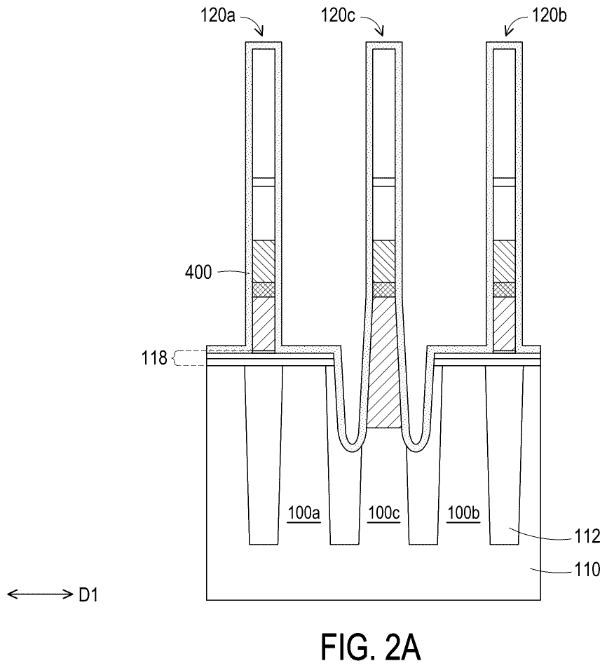

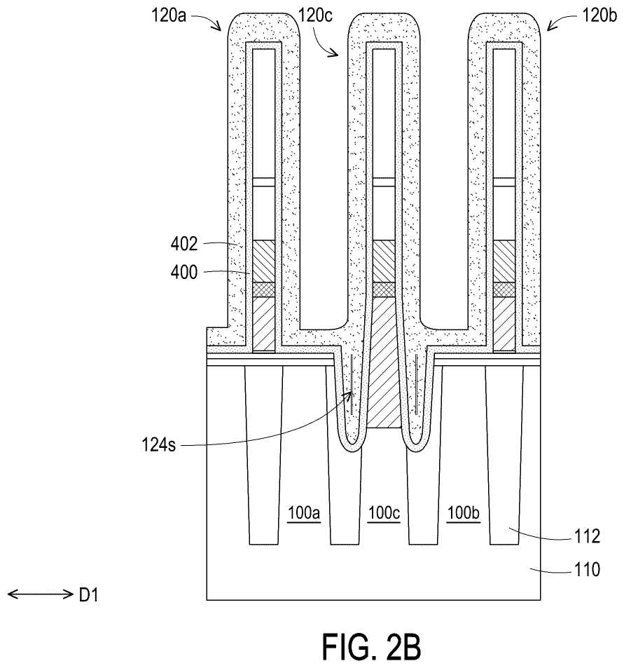

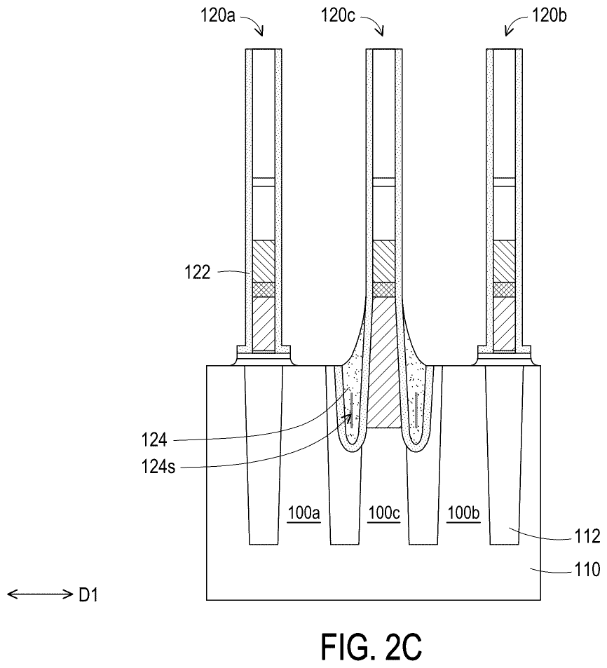

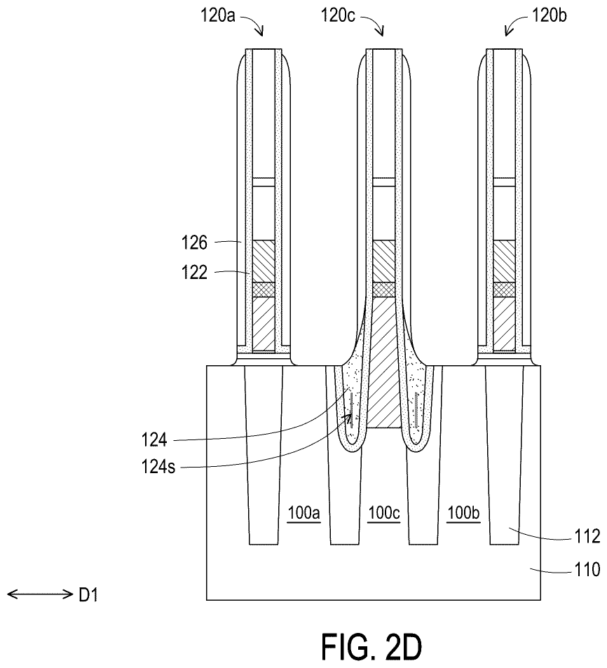

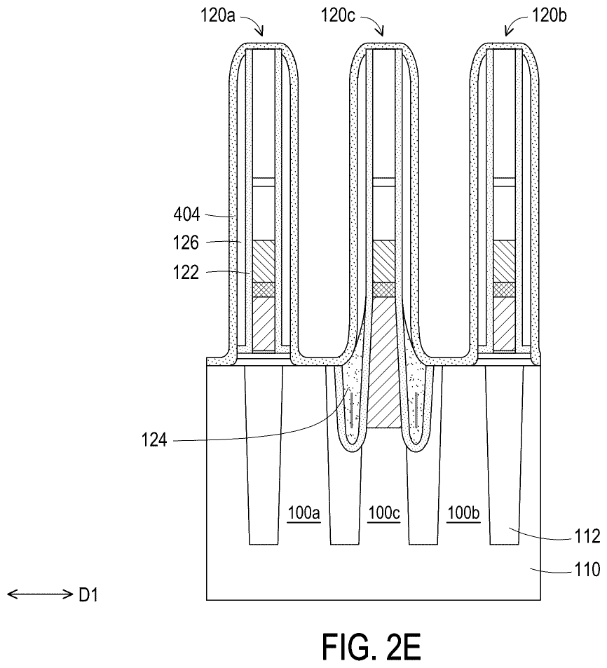

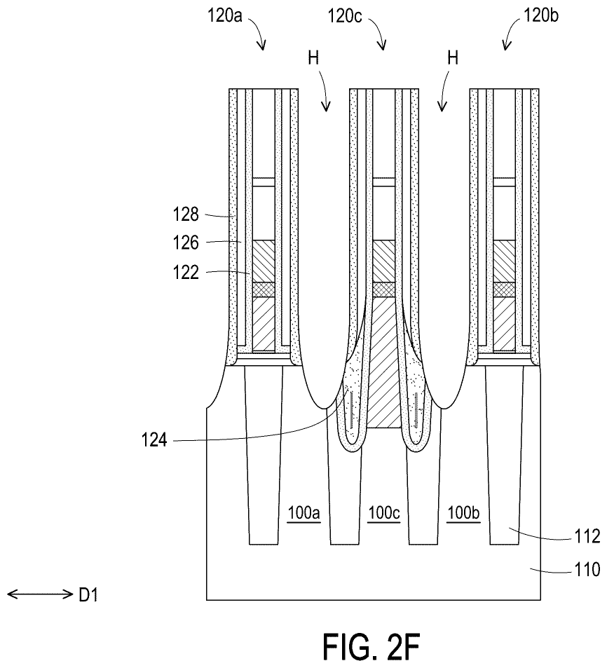

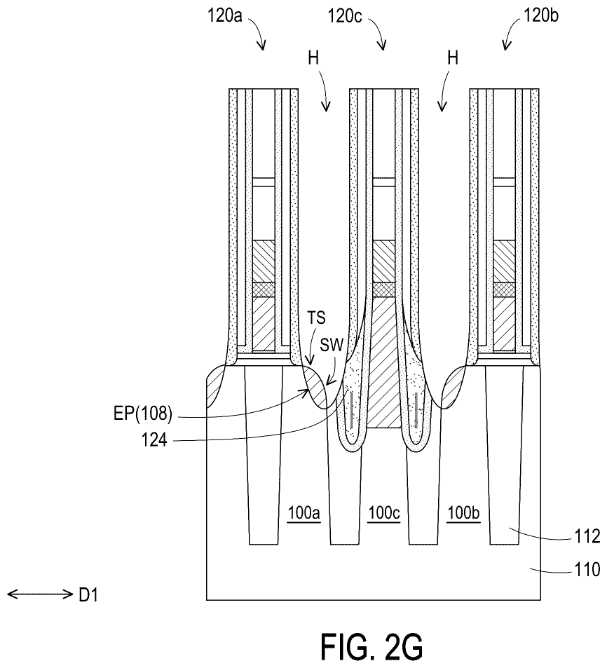

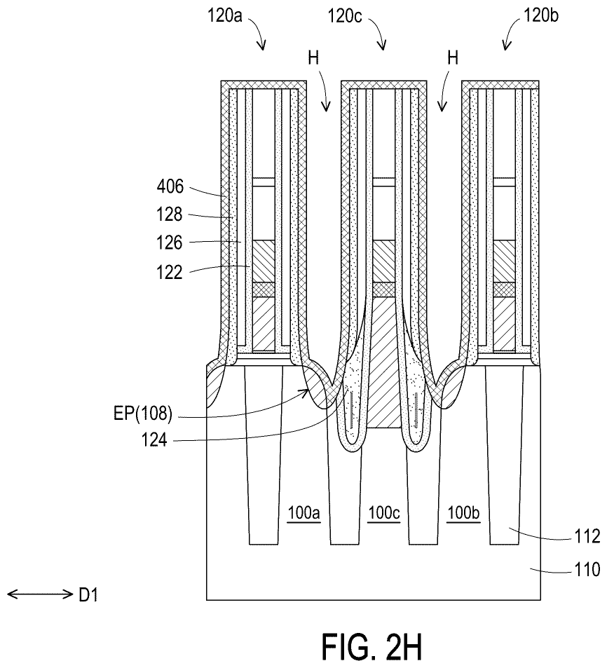

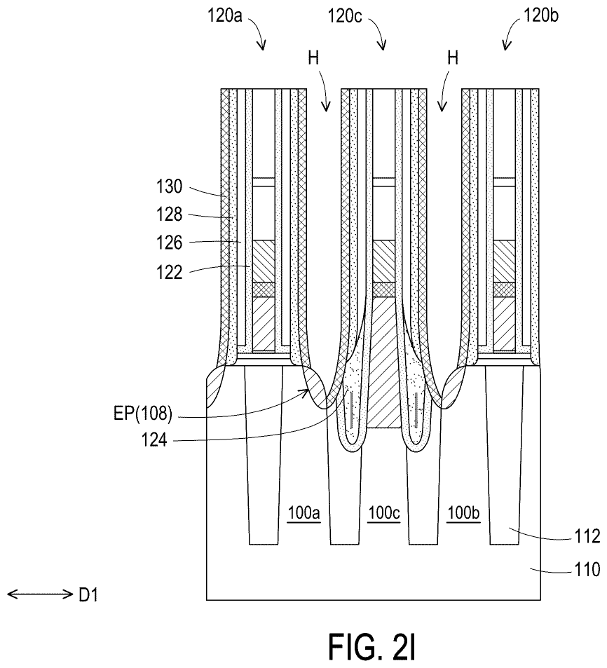

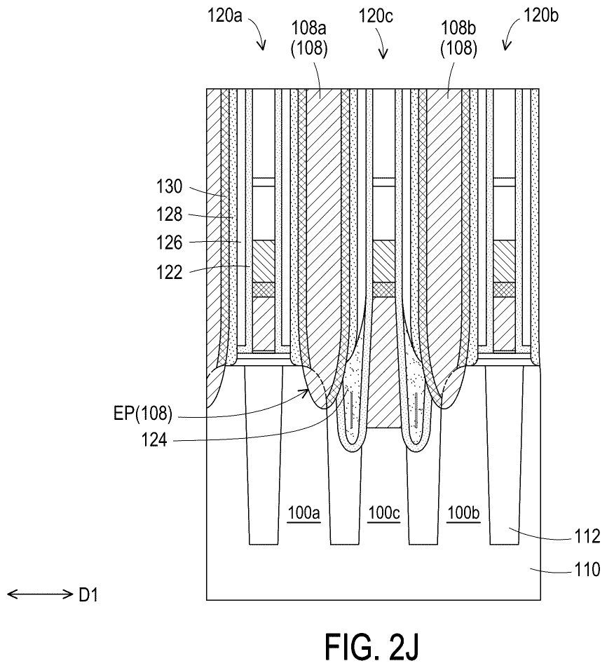

FIGS. 2A to 2J are schematic cross-sectional views along Line X-X′ of an intermediate structure at each stage of a manufacturing process of a semiconductor device 10.

In an initial stage, the bit line stack structure 120 (including the bit line stack structures 120a, 120b, and 120c) is formed on the substrate 110, on which the word line 102 (not shown) is formed, having the active regions 100 defined by the isolation structure 112. In some embodiments, the patterned insulated layer 118 may be formed on the substrate 110 before the bit line stack structure 120 is formed.

Referring to FIG. 2A, a spacer material layer 400 is formed. Thereafter, the spacer material layer 400 is patterned into the innermost spacer 122. Currently, the spacer material layer 400 may fully and conformally cover the substrate 110, the exposed isolation structure 112, and the bit line stack structure 120. In an embodiment where the insulation layer 118 is formed, the spacer material layer 400 also covers the insulation layer 118.

Referring to FIG. 2B, an insulating material layer 402 is formed. Thereafter, the insulating material layer 402 is patterned into the insulating material 124. Currently, the insulating material layer 402 fully and conformally covers the spacer material layer 400 and fills the recesses defined on two opposite sides of the bit line stack structure 120c. In some embodiments, the air gaps 124s are formed in a portion of the insulating material layer 402 located in the recesses.

Referring to FIG. 2C, the insulating material layer 402 and the spacer material layer 400 are patterned. At this stage, the insulating material layer 402 is patterned into the insulating material 124, and the spacer material layer 400 is patterned into the innermost spacer 122. In some embodiments, the patterning of the insulating material layer 402 and the spacer material layer 400 is realized by removing the lateral extended portions of the insulating material layer 402 and the spacer material layer 400 through anisotropic etching. As a result of the etching, a top surface of the insulating material 124 may extend, in a diagonally upward direction, from a lower side away from the bit line stack structure 120c to a higher side near the bit line stack structure 120c.

Referring to FIG. 2D, the spacer 126 is formed. In some embodiments, a method for forming the spacer 126 may include the following steps. A deposition operation is performed to form a spacer material layer that fully and conformally covers the structure shown in FIG. 2C, followed by an anisotropic etching operation to pattern the spacer material layer, thereby forming the spacer 126.

Referring to FIG. 2E, a spacer material layer 404 is formed. Thereafter, the spacer material layer 404 is patterned into the spacer 128. Currently, the spacer material layer 404 fully and conformally covers the structure shown in FIG. 2D.

Referring to FIG. 2F, an opening H is formed between the bit line stack structures 120 for accommodating the spacer 130 and the capacitor contact structure 108. Through photolithography and anisotropic etching operations, a portion of the spacer material layer 404 covering the top surface of the bit line stack structure 120 and a portion of the spacer material layer 404 extending laterally between the bit line stack structures 120 are removed, thereby patterning the spacer material layer 404 into the spacer 128 and forming the openings H. At this stage, the active region 100 (including the active regions 100a and 100b) and the isolation structure 112 located between the bit line stack structures 120 are exposed. Further, the spacer 122 and the insulating material 124 are also exposed. By continuing the anisotropic etching operation, the opening H is enabled to further extend into the exposed structure (including the active regions 100a and 100b as well as the isolation structure 112, further including the spacer 122 and the insulating material 124).

Referring to FIG. 2G, the epitaxial portion EP of the capacitor contact structure 108 is formed in the opening H. By performing a selective epitaxial growth operation, the epitaxial portion EP of the capacitor contact structure 108 may be selectively grown from a surface of the active region 100 (including the active regions 100a and 100b) exposed in the opening H. The epitaxial portion EP of the capacitor contact structure 108 may have multiple surfaces composed of several crystal planes. It should be understood that a surface of the epitaxial portion EP may vary depending on the epitaxial conditions and materials. For example, the epitaxial portion EP may have an upper surface TS facing directly upward and/or diagonally upward. The epitaxial portion EP may also have a side surface SW that extends longitudinally from the upper surface TS to a bottom end of the epitaxial portion EP. The upper surface TS and the side surface SW may be a planar surface, an inclined surface, or a curved surface respectively, but the disclosure is not limited thereto.

Referring to FIG. 2H, a spacer material layer 406 is formed in the opening H. Thereafter, the spacer material layer 406 is patterned into the spacer 130. Currently, the spacer material layer 406 fully and conformally covers the structure shown in FIG. 2G.

Referring to FIG. 2I, the spacer material layer 406 is patterned. By performing the anisotropic etching operation, a portion of the spacer material layer 406 outside of the opening H is removed. Moreover, a portion of the spacer material layer 406 covering the epitaxial portion EP of the capacitor contact structure 108 may also be removed. This way, the fully covering spacer material layer 406 is patterned into a spacer 130, disposed discretely in the opening H and exposing the epitaxial portion EP of the capacitor contact structure 108. In some embodiments, the patterning operation removes a portion of the spacer material layer 406 covering the upper surface TS of the epitaxial portion EP. On the other hand, a portion of the spacer material layer 406 covering the side surface SW of the epitaxial portion EP may be at least partially retained along with a portion covering the isolation structure 112, the spacer 122, the insulating material 124, and the spacer 128 to form the spacer 130. Alternatively, the portion of the spacer material layer 406 covering the side surface SW of the epitaxial portion EP may also be completely removed.

Referring to FIG. 2J, the remaining portion of the capacitor contact structure 108 is formed in the opening H. The remaining portion of the capacitor contact structure 108 may be filled in the opening H by performing the deposition operation. Although not shown, at this stage, the top surface of the capacitor contact structure 108 may be higher than the top surface of the bit line stack structure 120. Subsequently, a height of the top surface of the capacitor contact structure 108 is adjusted. For example, the top surface of the capacitor contact structure 108 may be lowered to a position lower than the top surface of the bit line stack structure 120 (as shown in FIG. 1B) through a combination of chemical mechanical polishing and etch back. Next, although not shown, a structure including a storage capacitor may further be formed on the current structure, thereby completing the manufacture of the memory device 10.

In summary, in the embodiments of the disclosure, a leakage path between the capacitor contact structure and the bit line as well as the bit line contact structure are better blocked by disposing the outermost spacer on a side wall of the bit line stack structure. Specifically, under the condition where an alignment error exists, the outermost spacer may still extend between the capacitor contact structure and the active region, preventing an unintended electrical connection between the capacitor contact structure and the adjacent bit line contact structure as well as the adjacent bit line through the active region.

What is claimed is:

1. A memory device, comprising:
a first active region and a second active region, located separately in a substrate;
a first word line and a second word line, extending along a first direction and penetrating the first active region and the second active region respectively;
a bit line stack structure, comprising a bit line extending along a second direction and intersecting the first active region from above the substrate, and a bit line contact structure located between the first word line and the second word line and connecting the bit line to the first active region;
a capacitor contact structure, connecting the second active region to a storage capacitor above and located between the first word line and the second word line; and
a spacer, covering a side wall of the capacitor contact structure and having a first portion extending between the bit line stack structure and the capacitor contact structure,
wherein the bit line contact structure extends into the first active region in a manner that a bottom end of the bit line contact structure is lower than a topmost surface of the substrate, and a bottom end of the first portion of the spacer is lower than the topmost surface of the substrate.

2. The memory device of claim 1, wherein the spacer surrounds the capacitor contact structure.

3. The memory device of claim 1, wherein the capacitor contact structure is separated from an isolation structure located between the first active region and the second active region by the first portion of the spacer.

4. The memory device of claim 3, wherein the first portion of the spacer extends downward and covers the isolation structure.

5. The memory device of claim 1, wherein the capacitor contact structure comprises an epitaxial portion, growing outwardly from the second active region, wherein the spacer contacts a bottom and a top of the epitaxial portion without completely covering the epitaxial portion.

6. The memory device of claim 1, further comprising an additional spacer, extending along a side wall of the bit line stack structure, wherein the additional spacer comprises a first spacer and a second spacer arranged outwardly from the bit line stack structure, and a bottom of the first spacer extends outwardly along a surface of a recess located on two opposite sides of the bit line stack structure and contacts the first portion of the spacer.

7. The memory device of claim 6, further comprising an insulating material, the insulating material filling the recess, wherein a bottom end of the second spacer extends into the insulating material.

8. The memory device of claim 7, wherein the first portion of the spacer covers the insulating material.

9. The memory device of claim 1, wherein the first active region only partially overlaps the bit line contact structure, and the first portion of the spacer extends between the capacitor contact structure and the first active region.

10. The memory device of claim 1, further comprising another bit line stack structure, wherein the spacer comprises a second portion extending between the capacitor contact structure and the another bit line stack structure, and a bottom end of the second portion of the spacer is substantially at a same height as the topmost surface of the substrate.

11. The memory device of claim 10, wherein the another bit line stack structure has a portion of an isolation structure disposed in the substrate, and a bottom surface of the portion of the another bit line stack structure is higher than the topmost surface of the substrate.

12. A manufacturing method of a memory device, comprising:
defining a first active region and a second active region separated from each other in a substrate;
forming a first word line and a second word line in the substrate, the first word line and the second word line extending along a first direction and penetrating the first active region and the second active region respectively;
forming a bit line stack structure on the substrate, wherein the bit line stack structure comprises a bit line extending along a second direction and intersecting the first active region from above the substrate, and a bit line contact structure located between the first word line and the second word line and connecting the bit line to the first active region;
forming a capacitor contact structure on the substrate, wherein the capacitor contact structure connects the second active region to a storage capacitor above and is located between the first word line and the second word line; and
forming a spacer extending between the bit line stack structure and the capacitor contact structure,
wherein the bit line contact structure extends into the first active region in a manner that a bottom end of the bit line contact structure is lower than a topmost surface of the substrate, and a bottom end of the spacer is lower than the topmost surface of the substrate.

13. The manufacturing method of the memory device of claim 12, wherein forming the capacitor contact structure comprises:
etching an opening for accommodating the capacitor contact structure, wherein the second active region is exposed at a bottom of the opening;
performing a selective epitaxial growth process to selectively grow an epitaxial portion of the capacitor contact structure in the exposed second active region; and
performing a deposition process to deposit a remaining portion of the capacitor contact structure on the epitaxial portion.

14. The manufacturing method of the memory device of claim 13, wherein forming the spacer comprises:
forming a spacer material layer covering a surface of the opening, wherein the epitaxial portion of the capacitor contact structure is located in the opening and covered by the spacer material layer; and
at least partially removing a portion of the spacer material layer covering the epitaxial portion so that a retained portion of the spacer material layer forms the spacer.

15. The manufacturing method of the memory device of claim 14, wherein the spacer is formed after etching the opening and performing the selective epitaxial growth process, and before performing the deposition process.

16. The manufacturing method of the memory device of claim 12, wherein before the spacer and the capacitor contact structure are formed, the manufacturing method of the memory device further comprises:
forming an additional spacer extending along a side wall of the bit line stack structure, wherein the additional spacer comprises a first spacer and a second spacer arranged outwardly from the bit line stack structure.

17. The manufacturing method of the memory device of claim 16, wherein forming the first spacer comprises forming a recess on two opposite sides of the bit line stack structure, and forming the first spacer along the side wall of the bit line stack structure and a surface of the recess, so that a bottom of the first spacer extends outwardly along the surface of the recess towards an outer side of the bit line stack structure, wherein the spacer formed thereafter contacts an outer edge of the first spacer.

18. The manufacturing method of the memory device of claim 17, wherein before the second spacer is formed, the manufacturing method of the memory device further comprises: forming an insulating material layer completely covering the substrate and the bit line stack structure and filling the recess; and patterning the insulating material layer to form an insulating material retained in the recess.

19. The manufacturing method of the memory device of claim 18, wherein forming the second spacer comprises: forming the second spacer along the first spacer and a surface of the insulating material.

20. The manufacturing method of the memory device of claim 19, wherein forming the second spacer comprises: forming a spacer material layer covering the bit line stack structure, the substrate, the first spacer, and the insulating material; and etching an opening for accommodating the capacitor contact structure, wherein a portion of the spacer material layer covering a top surface of the bit line stack structure and laterally extending along two opposite sides of the bit line stack structure is further removed by etching so as to pattern the spacer material layer into the second spacer longitudinally extending along the first spacer and the surface of the insulating material.
